(19) United States
(12) Patent Application Publication
(10) Pub. No.: US 2010/0297851 A1
(43) Pub. Date: Nov. 25, 2010

(54) COMPOSITIONS AND METHODS FOR MULTIPLE EXPOSURE PHOTOLITHOGRAPHY

(75) Inventors: Young Cheol BAE, Weston, MA (US); Yi Liu, Shrewsbury, MA (US); Thomas Cardolaccia, Newton, MA (US); Peter Trefonas, III, Medway, MA (US)

Correspondence Address: Jonathan D. Baskin;Rohm and Haas Electronic Materials LLC, 455 Forest Street, Marlborough, MA, 01752, US

(73) Assignee: Rohm and Haas Electronic Materials LLC, Marlborough, MA (US)

(21) Appl. No.: 12/781,486

(22) Filed: May 17, 2010

Related U.S. Application Data
(60) Provisional application No. 61/216,609, filed on May 19, 2009.

(51) Int. Cl. H01L 21/306; G03F 7/004

(52) U.S. Cl. 438/735; 430/270.1; 257/E21.215

(57) ABSTRACT

Compositions for use in multiple exposure photolithography and methods of forming electronic devices using a multiple exposure lithographic process are provided. The compositions find particular applicability in semiconductor device manufacture for making high-density lithographic patterns.

This application claims the benefit of priority under 35 U.S.C. §119(e) to U.S. Provisional Application No. 61/216,609, filed May 19, 2009, the contents of which application are incorporated herein by reference.

This invention relates to compositions suitable for use in multiple exposure photolithographic processes. The invention also relates to methods of forming electronic devices using multiple exposure photolithography. The compositions and methods find particular use in the manufacture of semiconductor devices for forming high-density lithographic patterns and features.

In the semiconductor manufacturing industry, photoresist materials are used for transferring an image to one or more underlying layers, such as metal, semiconductor and dielectric layers, disposed on a semiconductor substrate, as well as to the substrate itself. To increase the integration density of semiconductor devices and allow for the formation of structures having dimensions in the nanometer (nm) range, photoresists and photolithography processing tools having high-resolution capabilities have been and continue to be developed.

One approach to achieving nm-scale feature sizes in semiconductor devices is the use of short wavelengths of light, for example, 193 nm or less, during resist exposure. Immersion lithography effectively increases the numerical aperture (NA) of the lens of the imaging device, for example, a scanner having a KrF or ArF light source. This is accomplished by use of a relatively high refractive index fluid (i.e., an immersion fluid) between the last surface of the imaging device and the upper surface of the semiconductor wafer. The immersion fluid allows a greater amount of light to be focused into the resist layer than would occur with an air or inert gas medium. When using water as the immersion fluid, the maximum numerical aperture can be increased, for example, from 1.2 to 1.35. With such an increase in numerical aperture, it is possible to achieve a 40 nm half-pitch resolution in a single exposure process, thus allowing for improved design shrink. This standard immersion lithography process, however, is generally not suitable for manufacture of devices requiring greater resolution, for example, for the 32 nm and 22 nm half-pitch nodes.

In an effort to achieve greater resolution and to extend capabilities of existing manufacturing tools, various double patterning (also referred to as pitch splitting) techniques have been proposed. Examples of such techniques include double-etch double-patterning (DEDP) and double-expose single-etch double-patterning (SEDP) processes. In the double-etch double-patterning process, a first photoresist layer is coated on the substrate and is exposed and developed to form a first resist pattern. The resist pattern is transferred to an underlying hardmask layer by etching, and the resist is removed. A second photoresist layer is coated over the hardmask layer, and is exposed and developed to form a second resist pattern which includes lines disposed between adjacent lines of the hardmask layer. This double-pattern, including the patterned hardmask layer and second resist pattern, is then transferred by etching into one or more underlying layers. The DEDP process is disadvantageous in that the wafers are moved out of and back into the photolithography processing module to perform the intermediate etch and resist removal processes. Such movement of the wafers as well as the etching and resist removal processes themselves can be sources of contamination, thereby increasing defectivity. Additionally, the DEDP process requires a relatively large number of process steps which can result in a lower than desired production throughput.

Single-etch double-patterning techniques address the above-described problems associated with the DEDP process by use of two photoresist layers and a single etch step to transfer the resist pattern into the underlying layer(s) to be patterned. The SEDP process requires an additional process to cure, or stabilize, the first lithography pattern for the subsequent second lithography process. This stabilization process typically entails inter-molecular and intra-molecular cross-linking reactions in the bulk or on the surface of the first resist pattern. Whether pattern stabilization occurs in the resist pattern bulk or surface, the curing process should avoid or minimize pattern deformation during curing, intermixing between first and second resist layers and development of the first resist pattern during development of the second resist layer. A first example of a single-etch double-patterning process uses a thermal cure for the first resist pattern. After exposing and developing a first photoresist layer, the resulting pattern is cured in a high-temperature bake, typically at a temperature greater than 170° C. A second photoresist layer is coated over the layers to be etched and the cured first resist pattern, and is exposed and developed to form lines between adjacent lines of the cured first resist pattern. The first and second resist patterns are then transferred by etching into the underlying layers. Because of the high temperature involved in the first resist pattern cure, pattern deformation can result. In the case of such pattern deformation, intended features of the first resist pattern cannot be accurately transferred to the underlying layers.

In a second example of a single-etch double-patterning process, the first resist pattern is chemically cured by use of a resist-curing overcoat layer disposed over the first resist pattern. Components of the photoresist composition and overcoat layer react with heat to form a cured surface region in the first photoresist pattern. Double patterning techniques involving overcoat chemical curing systems have been disclosed, for example, in U.S. Patent App. Pub. No. US 2008/0199814 A1, to Brzozowy et al. That document discloses the use of a fixer solution comprising a solvent and a fixer compound containing at least two functional groups reactive with an anchor group in a resist polymer. The resists described in the document include silicon-containing polymers. It would, however, be desired to have a resist curing composition compatible with a variety of photoresists including those commonly used at sub-400 nm, sub-300 or sub-200 nm exposure wavelengths, which need not be silicon-based.

There is a continuing need in the art for compositions that are suitable for use in multiple exposure lithographic processes. As well, there is a need for methods of forming electronic devices using such compositions in a multiple exposure lithographic process and for electronic devices formed from such processes. The compositions and methods address one or more of the problems associated with the state of the art.

In accordance with a first aspect of the invention, provided are compositions suitable for use in a multiple exposure lithographic process. The compositions comprise: a matrix polymer; a crosslinker; a tri- or higher order-functional primary amine; and a solvent. In accordance with a further aspect of the invention, the compositions can include a multifunctional aromatic methanol derivative.

In accordance with a further aspect of the invention, methods of forming an electronic device using a multiple exposure lithographic process are provided. The methods comprise: (a) providing a semiconductor substrate comprising one or more layers to be patterned; (b) applying a layer of a first photosensitive composition over the one or more layers to be patterned; (c) exposing the layer of the first photosensitive composition to activating radiation through a first photomask; (d) heat-treating the exposed layer of the first photosensitive composition in a first post-exposure bake; (e) developing the exposed, heat-treated layer of the first photosensitive composition to form a first resist pattern; (f) applying a layer of a resist-curing composition over the one or more layers to be patterned and the first resist pattern, the resist-curing composition comprising a matrix polymer, a crosslinker, a tri- or higher order-functional primary amine and a solvent; (g) heat-treating the resist-curing composition-coated substrate, thereby curing at least a portion of the first resist pattern; (h) removing excess resist-curing composition from the substrate; (i) applying a layer of a second photosensitive composition over the one or more layers to be patterned and the first resist pattern; (j) exposing the layer of the second photosensitive composition to activating radiation through a second photomask; (k) heat-treating the exposed layer of the second photosensitive composition in a second post exposure bake; (l) developing the exposed, heat-treated layer of the second photosensitive composition to form a second resist pattern; and (m) etching the one or more layers to be patterned using the first and second resist patterns simultaneously as an etching mask.

In a further aspect, provided are electronic device substrates having one or more layers to be etched over a substrate, a photoresist pattern over the layers to be etched and a resist-curing composition layer formed from a resist-curing composition as described herein, the resist-curing composition layer being disposed over the photoresist pattern.

In a further aspect, electronic devices formed in accordance with the methods described herein are provided.

The present invention will be discussed with reference to the following drawings, in which like reference numerals denote like features, and in which:

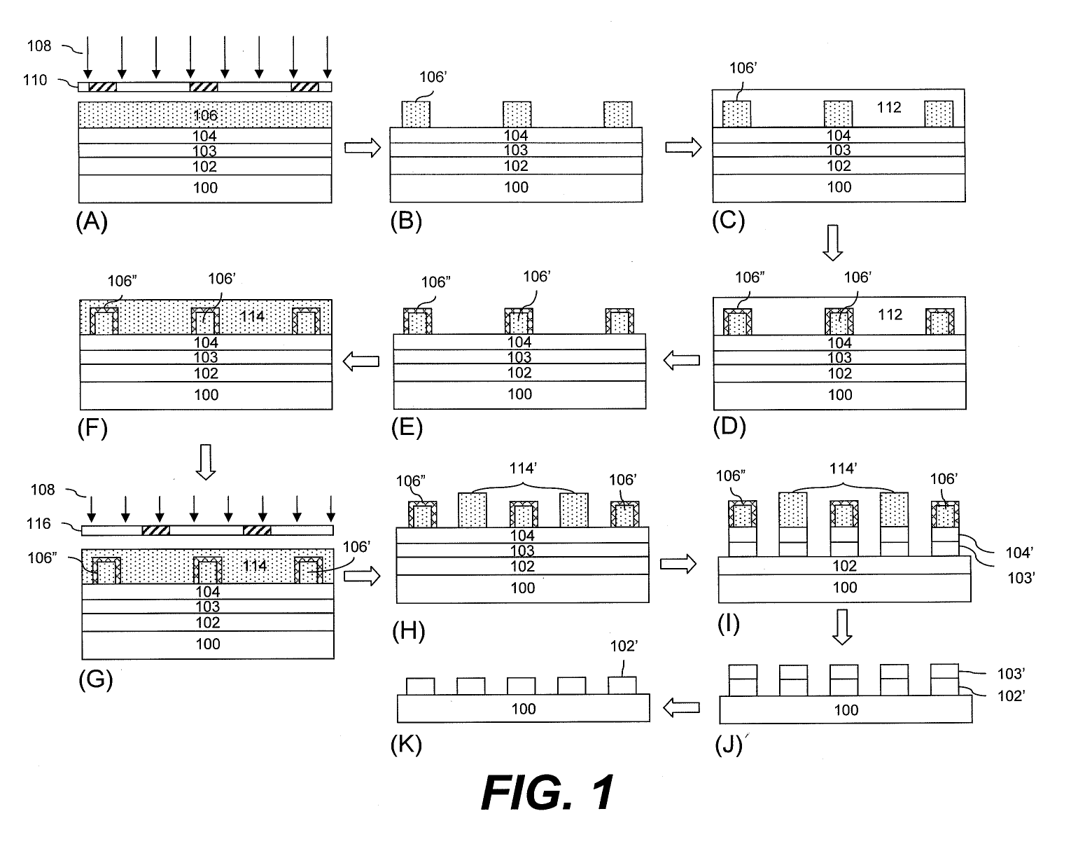

FIGS. 1A-K illustrate a single-etch double-exposure photolithographic process flow for forming an electronic device, in accordance with an exemplary aspect of the invention; and

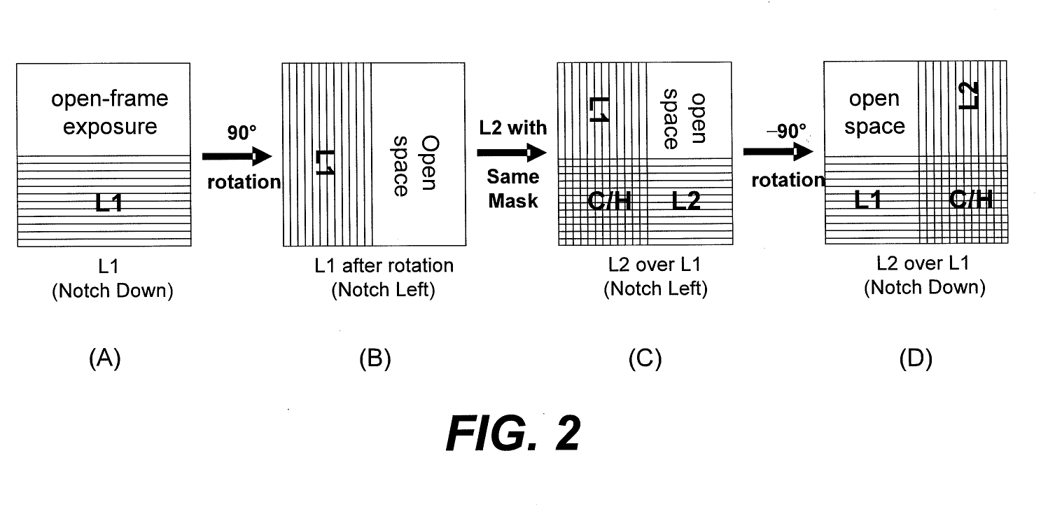

FIGS. 2A-D illustrate a photomask and exposure technique for forming double pattern cross-line structures on a semiconductor wafer.

### RESIST-CURING COMPOSITIONS

A first aspect of the invention provides compositions which are useful in photolithographic processes in general, and find particular applicability in multiple exposure lithography. The compositions can be used as an overcoat material for chemically curing an underlying photoresist pattern in single exposure and multiple exposure lithography processes, for example, in a single etch double, triple or higher order patterning process. The compositions include a matrix polymer, a crosslinker, a tri- or higher order-functional primary amine and a solvent. The compositions can further include one or more optional components such as a multifunctional aromatic methanol derivative or a surfactant. As used herein, the terms “a” and “an” are inclusive of one or more. Thus, one or more of each of the listed components can be present in the compositions of the invention.

The matrix polymer aids in the formation of a uniform coating of the resist-curing composition over a resist pattern. This component should be soluble in the solvent, and is typically inert with respect to the other components of the resist-curing composition. The matrix polymer should additionally provide a sufficiently high dissolution rate in a remover material such as deionized (DI) water and/or aqueous base developer such as tetramethylammonium hydroxide solutions (TMAH), for example, a 2.38 weight percent (wt %) TMAH solution. The matrix polymer is typically alcohol-soluble and aqueous base-soluble.

The matrix polymer can include one or more type of repeating units, with one type of repeating unit being typical. Optionally, a plurality such as two, three or more distinct matrix polymers can be employed. Exemplary suitable matrix polymers include polyvinylpyrrolidone, poly(hydroxystyrene), polyvinyl alcohol, poly(ethylene oxide), polypropylene oxide) and combinations thereof. The matrix polymer component is typically present in the resist-curing composition in the largest proportion of all of the solid components on an individual basis such that it forms a major portion of the formed resist-curing overcoat layer. As used herein, the term “solids” and “solid components” with reference to a composition, means all components of the composition other than the solvent component.

The matrix polymer is typically present in the composition in an amount of from 70 to 90 wt %, for example, from 75 to 85 wt %, based on the total solids of the composition.

The resist-curing compositions of the invention further include one or more crosslinker. This component is believed to promote cross-linking reactions under elevated temperature within and/or between one or more of the primary amine, the optional multifunctional aromatic methanol derivative, the underlying resist polymer, for example, a deprotected portion of the polymer chain in the case of a positive-acting material. Suitable crosslinkers include, for example, those having the following general formula (G-I):

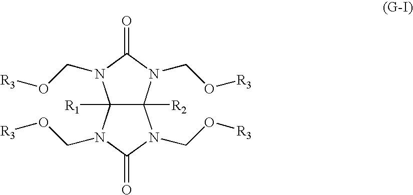

wherein: R₁ and R₂ are independently chosen from hydrogen and optionally substituted alkyl such as C1 to C6 alkyl, alkenyl, alkoxy and aryl; and R₃ is chosen from optionally substituted alkyl such as C1 to C6 alkyl, typically methyl. Suitable crosslinkers of formula (G-I) include, for example, those having the following structures:

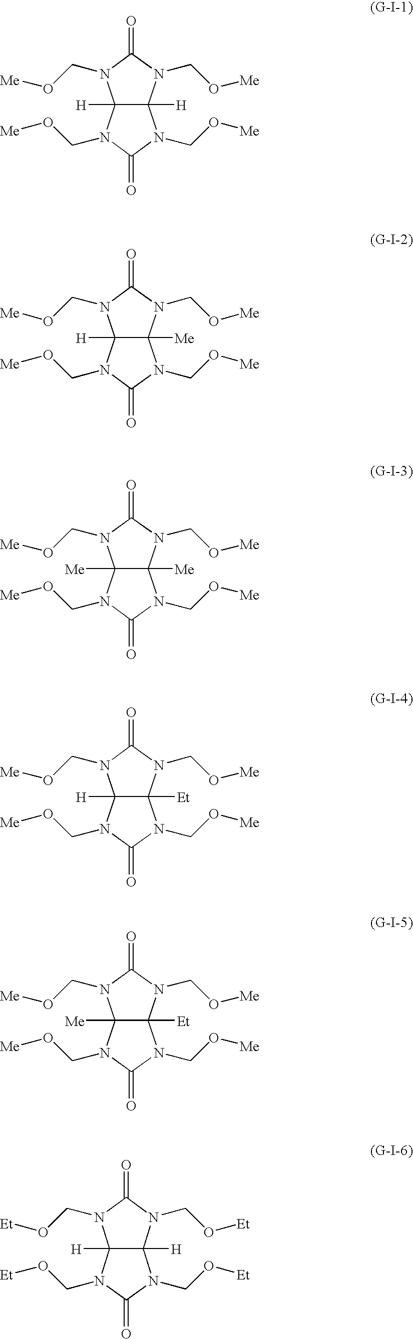

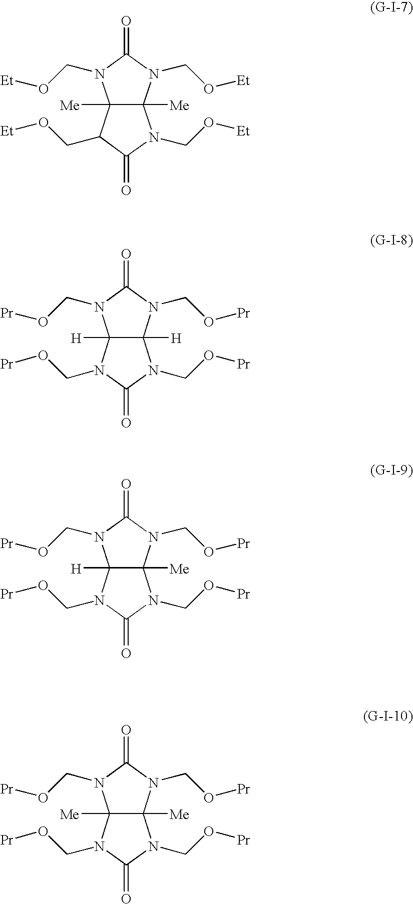

Other suitable crosslinkers include, for example, those of the following general formula (G-II):

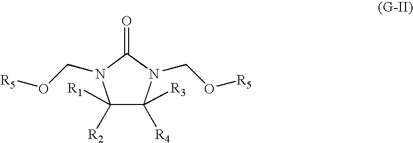

wherein: R₁, R₂, R₃ and R₄ are independently chosen from hydrogen, optionally substituted alkyl such as C1 to C6 alkyl, alkenyl, alkoxy and aryl; and R₅ is chosen from optionally substituted alkyl such as C1 to C6 alkyl, typically methyl. Suitable crosslinkers of formula (G-II) include, for example, those having the following structures:

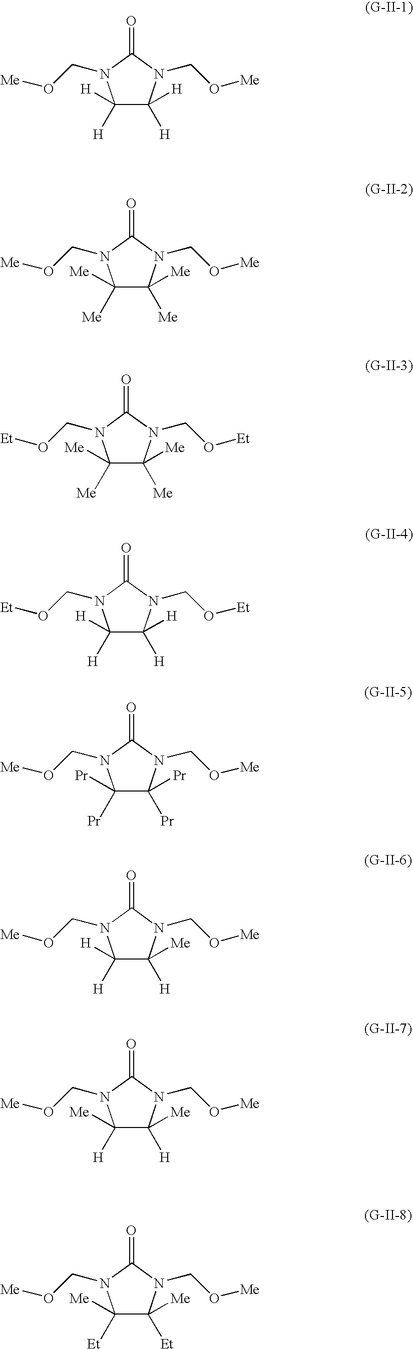

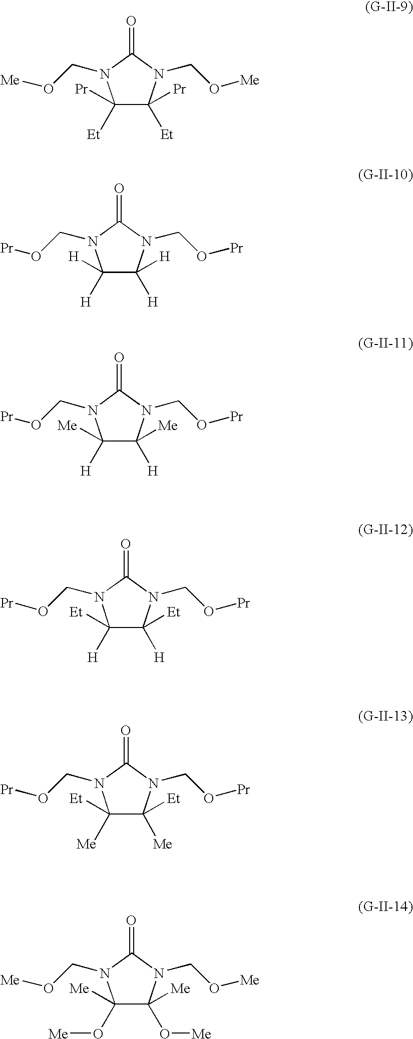

Other suitable crosslinkers include, for example, those of the following general formula (G-III):

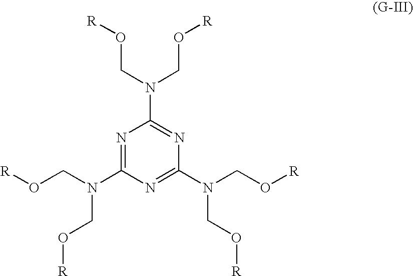

wherein: R is chosen from optionally substituted alkyl such as C1 to C6 alkyl, typically methyl.

The crosslinker is typically present in the composition in an amount of from 5 to 20 wt %, for example, from 5 to 15 wt %, based on the total solids of the composition.

The composition further includes one or more tri- or higher order-functional primary amine, i.e., an amine including three or more primary amine groups. Secondary and/or tertiary amine groups can be present in addition to the primary amine groups. This component is believed to function as a quencher for acid-catalyzed reactions among components of the composition at the surface of a photoresist pattern. The primary amine may also react with the optional multifunctional aromatic methanol to result in further cross-linking in forming a cross-linked layer at the surface of the resist. The primary amine can be a polyamine, such as a diamine, triamine or tetra-amine. Suitable primary amines include compounds of the following formula (N-I):

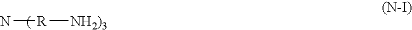

wherein R is chosen from optionally substituted alkyl such as optionally substituted C1 to C6 alkyl, such as methyl, ethyl or propyl, with ethyl being typical. Other suitable primary amines include poly(allyl amines) represented by the following formula (N-II):

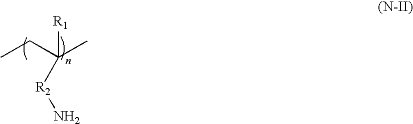

wherein: R₁ is chosen from hydrogen and optionally substituted alkyl such as C1 to C3 alkyl; R₂ is chosen from optionally substituted alkylene such as C1 to C6 alkylene, typically methylene or ethylene; and n is an integer greater than or equal to 3. In an exemplary primary amine of the formula (N-II), R₁ is hydrogen and R₂ is methylene.

The primary amine is typically present in the composition in an amount of from 1 to 5 wt %, for example, from 2 to 3 wt %, based on the total solids of the composition.

The resist-curing compositions further include one or more solvents to aid in formulating and casting the compositions. Suitable solvent materials include those which dissolve or disperse the components of the composition while only minimally dissolving or, more preferably, not dissolving the underlying photoresist pattern. The solvents useful in forming the resist-curing compositions are thus not good solvents for the polymers in the resist pattern to which the resist-curing compositions are applied. Suitable solvents include both polar and non-polar materials. Suitable polar solvents include, for example: alcohols such as C3 to C8 n-alcohols, such as isopropanol, n-butanol, 2-butanol, isobutanol, 2-methyl-1-butanol, isopentanol, 2,3-dimethyl-1-butanol, 4-methyl-2-pentanol, isohexanol and isoheptanol, isomers thereof and mixtures thereof; alkylene glycols such as propylene glycol; alkyl ethers such as isopentyl ether; and hydroxy alkyl ethers such as those of the formula (E-I):

R₁—O—R₂—O—R₃—OH (E-I)

Wherein: R₁ is an optionally substituted alkyl group such as C1 to C4 alkyl group; and R₂ and R₃ are independently chosen from optionally substituted alkyl groups such as C2 to C4 alkyl groups; and mixtures of such hydroxy alkyl ethers including isomeric mixtures, for example, dialkyl glycol mono-alkyl ethers such as diethylene glycol monomethyl ether and dipropylene glycol monomethyl ether; and combinations thereof, for example, an alcohol and an alkyl ether. Use of an alcohol and/or an alkyl ether is typical.

Suitable non-polar solvents include, for example: aliphatic hydrocarbons, for example, alkanes such as octane, isooctane, decane and dodecane; aromatic hydrocarbons such as mesitylene and xylene including isomers thereof; and combinations thereof.

One or more solvent in the solvent system can individually be in a substantially pure form, meaning isomers of the solvent molecule are present in that solvent in an amount less than 5 wt %, for example, less than 2 wt % or less than 1 wt %. Optionally, the solvent can include a mixture of isomers of the solvent molecule, wherein the isomers are present in an amount greater than 5 wt %, for example, greater than 10 wt %, greater than 20 wt %, greater than 40 wt %, greater than 60 wt %, greater than 80 wt % or greater than 90 wt %.

The solvent is typically present in the composition in an amount of from 90 to 98 wt %, for example, from 95 to 97 wt %, and typically about 96 wt %, based on the total composition.

The resist-curing compositions can also contain one or more optional components. For example, the resist-curing composition can optionally further include one or more multifunctional aromatic methanol derivative. This component is believed to crosslink with the crosslinker. Suitable multifunctional aromatic methanol derivatives include, for example, benzenemethanol derivatives of the following general formula (M-I):

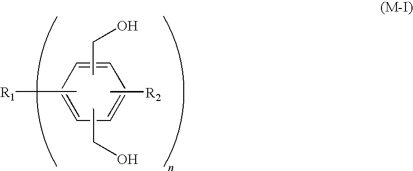

wherein: R₁ and R₂ are independently chosen from hydrogen, hydroxy and optionally substituted alkyl, alkenyl, alkoxy and aryl; and n is an integer greater than or equal to 1. Suitable multifunctional aromatic methanol derivatives of formula (M-I) include, for example, those having the following structures:

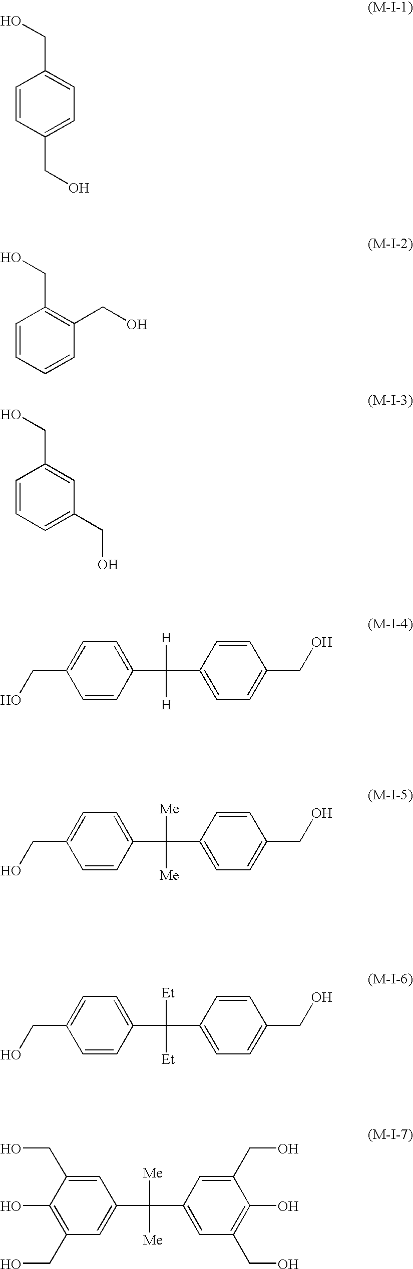

The multifunctional aromatic methanol derivative, if used, is typically present in the composition in an amount of up to 12 wt %, such as from 1 to 10 wt %, for example, from 3 to 5 wt %, based on the total solids of the composition.

The resist curing compositions may further optionally include one or more additives such as one or more surfactant. The use of surfactants in the resist-curing compositions can promote formation of a substantially uniform coating layer of the composition over a patterned substrate such as a patterned wafer. A variety of surfactants may be employed. Typical surfactants exhibit an amphiphilic nature, meaning that they can be both hydrophilic and hydrophobic at the same time. Amphiphilic surfactants possess a hydrophilic head group or groups, which have a strong affinity for water and a long hydrophobic tail, which is organophilic and repels water. Suitable surfactants may be ionic (i.e., anionic, cationic) or nonionic. Further examples of surfactants include silicone surfactants, poly(alkylene oxide) surfactants, and fluorochemical surfactants such as POLYFOX® PF-636 AND PF-656 (Omnova Solutions Inc.). Suitable non-ionic surfactants include, but are not limited to, octyl and nonyl phenol ethoxylates such as TRITON® X-114, X-102, X-45, X-15, and alcohol ethoxylates such as BRIJ® 56 (C₁₆H₃₃ (OCH₂CH₂)₁₀OH)(ICl), BRIJ® 58 (C₁₆H₃₃(OCH₂CH₂) 20 OH)(ICl). Still further exemplary surfactants include alcohol (primary and secondary) ethoxylates, amine ethoxylates, glucosides, glucamine, polyethylene glycols, poly(ethylene glycol-co-propylene glycol), or other surfactants disclosed in McCutcheon's Emulsifiers and Detergents, North American Edition for the Year 2000 published by Manufacturers Confectioners Publishing Co. of Glen Rock, N.J. Nonionic surfactants that are acetylenic diol derivatives also can be suitable.

The one or more surfactants can be suitably present in relatively small amounts, for example, less than: 5 wt %, 4 wt %, 3 wt %, 2 wt %, 1 wt % or 0.5 wt % based on the total solids of the composition.

The resist-curing compositions may be suitably prepared by admixture of the components in any order. For example, the non-solvent components of the composition, i.e., the matrix polymer, crosslinker, tri- or higher order-functional primary amine and optional components such as a multifunctional aromatic methanol derivative and surfactant, can be admixed into the solvent. Optionally, one or more of the non-solvent components can be combined with a solvent prior to combining with the remaining components.

Photoresist Materials

Advantageously, the resist-curing overcoat layer compositions of the invention can be used with a variety of photosensitive materials in multiple exposure lithography. As used herein, the terms “photosensitive material(s)” and “photoresist(s)” are used interchangeably. Suitable photoresist materials are known in the art and include, for example, those based on acrylate, novolak and silicon chemistries. Suitable resists are described, for example, in U.S. Application Publication Nos. US20090117489 A1, US20080193872 A1, US20060246373 A1 and U.S. Pat. No. 7,332,616.

The photosensitive materials employed in the multiple exposure lithography processes of the invention include (i) those used in forming photoresist patterns to be stabilized by the resist-curing compositions, and will typically include (ii) those used to form resist patterns to be cured in a conventional thermal treatment. For example, in the case of a typical double exposure double patterning process, the first-formed resist pattern can be chemically cured by use of the resist-curing compositions, typically accompanied by a low temperature thermal treatment, while the second-faulted resist pattern can be cured solely by a conventional thermal treatment.

Typical photoresist materials useful for forming both types (i) and (ii) resist patterns include positive-acting chemically amplified photoresists which undergo a photoacid-promoted deprotection reaction of acid labile groups of one or more components of the composition to render exposed regions of a coating layer of the resist more soluble in an aqueous developer than unexposed regions.

Typical photoacid-labile groups of the photoresist resins include ester groups that contain a tertiary non-cyclic alkyl carbon (e.g., t-butyl) or a tertiary alicyclic carbon (e.g., methyladamantyl) covalently linked to the carboxyl oxygen of the ester. Acetal photoacid-labile groups also are typical. The photoresists typically comprise a resin component and a photoactive component. Typically, the resin has functional groups that impart alkaline aqueous developability to the resist composition. For example, typical are resin binders that comprise polar functional groups such as hydroxyl or carboxylate. Typically, a resin component is used in a resist composition in an amount sufficient to render the resist developable with an aqueous alkaline solution.

For imaging at sub-200 nm wavelengths such as 193 nm, a typical photoresist contains one or more polymers that are substantially, essentially or completely free of phenyl or other aromatic groups. For example, for sub-200 nm imaging, typical photoresist polymers contain less than about 5 mole percent (mole %) aromatic groups, less than about 1 or 2 mole % aromatic groups or no aromatic groups. Aromatic groups can be highly absorbing of sub-200 nm radiation and thus are generally undesirable for polymers used in photoresists imaged with such short wavelength radiation.

Suitable polymers that are substantially or completely free of aromatic groups and that may be formulated with a photoacid generator (PAG) to provide a photoresist for sub-200 nm imaging are disclosed in European Published Application EP930542A1 and U.S. Pat. Nos. 6,692,888 and 6,680,159. Suitable polymers that are substantially or completely free of aromatic groups suitably contain acrylate units such as photoacid-labile acrylate units as may be provided by polymerization of methyladamantylacrylate, methyladamantylmethacrylate, ethylfenchylacrylate, ethylfenchylmethacrylate, and the like; fused non-aromatic alicyclic groups such as may be provided by polymerization of a norbornene compound or other alicyclic compound having an endocyclic carbon-carbon double bond; an anhydride such as may be provided by polymerization of maleic anhydride and/or itaconic anhydride; and the like.

The resin component of resists useful in the invention are typically used in an amount sufficient to render an exposed coating layer of the resist developable such as with an aqueous alkaline solution. More particularly, a resin binder will suitably comprise 50 to about 90 wt % of total solids of the resist.

The resist compositions useful in the invention also include a photoactive component employed in an amount sufficient to generate a latent image in a coating layer of the resist upon exposure to activating radiation. For example, the photoactive component will suitably be present in an amount of from about 1 to 40 wt % of total solids of the resist. Typically, lesser amounts of the photoactive component will be suitable for chemically amplified resists.

Typical photoactive components in the resist compositions are photoactid generators. Suitable PAGs are known in the art of chemically amplified photoresists and include, for example: onium salts, for example, triphenyl sulfonium salts such as triphenylsulfonium trifluoromethanesulfonate, (p-tert-butoxyphenyl)diphenylsulfonium trifluoromethanesulfonate, tris(p-tert-butoxyphenyl)sulfonium trifluoromethanesulfonate, triphenylsulfonium p-toluenesulfonate, (p-tert-butoxyphenyl)diphenylsulfonium p-toluenesulfonate, tris(p-tert-butoxyphenyl)sulfonium p-toluenesulfonate, trinaphthylsulfonium trifluoromethanesulfonate, cyclohexylmethyl(2-oxocyclohexyl)sulfonium trifluoromethanesulfonate, (2-norbornyl)methyl(2-oxocyclohexyl)sulfonium trifluoromethanesulfonate, and 1,2′-naphthylcarbonylmethyltetrahydrothiophenium trifluoromethanesulfonate; nitrobenzyl derivatives, for example, 2-nitrobenzyl p-toluenesulfonate, 2,6-dinitrobenzyl p-toluenesulfonate, and 2,4-dinitrobenzyl p-toluenesulfonate; sulfonic acid esters, for example, 1,2,3-tris(methanesulfonyloxy)benzene, 1,2,3-tris(trifluoromethanesulfonyloxy)benzene, and 1,2,3-tris(p-toluenesulfonyloxy)benzene; diazomethane derivatives, for example, bis(benzenesulfonyl)diazomethane, bis(p-toluenesulfonyl)diazomethane, bis(2,4-dimethylphenylsulfonyl)diazomethane, bis(1,1-dimethylethylsulfonyl)diazomethane, bis(cyclohexylsulfonyl)diazomethane, and bis(n-butylsulfonyl)diazomethane; glyoxime derivatives, for example, bis-O-(p-toluenensulfonyl)-α-dimethylglyoxime, and bis-O-(n-butanesulfonyl)-α-dimethylglyoxime; sulfonic acid ester derivatives of an N-hydroxyimide compound, for example, N-hydroxysuccinimide methanesulfonic acid ester, N-hydroxysuccinimide trifluoromethanesulfonic acid ester, N-hydroxysuccinimide 1-propanesulfonic acid ester, N-hydroxyimide p-toluenesulfonic acid ester, N-hydroxynaphthalimide methanesulfonic acid ester, and N-hydroxynaphthalimide benzenesulfonic acid ester; and halogen-containing triazine compounds, for example, 2-(4-methoxyphenyl)-4,6-bis(trichloromethyl)-1,3,5-triazine, 2-(4-methoxynaphthyl)-4,6-bis(trichloromethyl)-1,3,5-triazine, 2-[2-(2-furyl)ethenyl]-4,6-bis(trichloromethyl)-1,3,5-triazine, 2-[2-(5-methyl-2-furyl)ethenyl]-4,6-bis(trichloromethy)-1,3,5-triazine, and 2-[2-(3,5-dimethoxyphenyl)ethenyl]-4,6-bis(trichloromethyl)-1,3,5-triazine. One or more of such PAGs can be used.

A typical optional additive of the resists is an added base, particularly tetrabutylammonium hydroxide (TBAH), or tetrabutylammonium lactate, which can enhance resolution of a developed resist relief image. For resists imaged at 193 nm, a typical added base is a hindered amine such as diazabicyclo undecene or diazabicyclononene. The added base is suitably used in relatively small amounts, for example, about 0.03 to 5 wt % relative to the total solids.

Photoresists used in accordance with the invention also may contain other optional materials. For example, other optional additives include anti-striation agents, plasticizers and speed enhancers. Such optional additives typically will be present in minor concentrations in a photoresist composition except for fillers and dyes which may be present in relatively large concentrations, for example, in amounts of from about 5 to 30 wt % based on the total weight of a resist's dry components.

Negative-acting photoresists also find use in the invention, for example, in forming the type (ii) resist patterns. Suitable negative-acting resists typically will contain a crosslinking component. The crosslinking component is typically present as a separate resist component. Amine-based crosslinkers such as a melamine, for example, the Cymel melamine resins, are typical. Negative-acting photoresist compositions useful in the invention comprise a mixture of materials that will cure, crosslink or harden upon exposure to acid, and a photoactive component of the invention. Particularly useful negative acting compositions comprise a resin binder such as a phenolic resin, a crosslinker component and a photoactive component. Such compositions and the use thereof are disclosed in European Patent Nos. EP0164248B1 and EP0232972B1, and in U.S. Pat. No. 5,128,232. Typical phenolic resins for use as the resin binder component include novolaks and poly(vinylphenol)s such as those discussed above. Typical crosslinkers include amine-based materials, including melamine, glycolurils, benzoguanamine-based materials and urea-based materials. Melamine-formaldehyde resins are generally most typical. Such crosslinkers are commercially available, for example: the melamine resins sold by Cytec Industries under the trade names Cymel 300, 301 and 303; glycoluril resins sold by Cytec Industries under the trade names Cymel 1170, 1171, 1172; urea-based resins sold by Teknor Apex Company under the trade names Beetle 60, 65 and 80; and benzoguanamine resins sold by Cytec Industries under the trade names Cymel 1123 and 1125. For imaging at sub-200 nm wavelengths such as 193 nm, typical negative-acting photoresists are disclosed in International Application Pub. No. WO 03077029.

The photoresists useful in the invention are generally prepared following known procedures. For example, a resist can be prepared as a coating composition by dissolving the components of the photoresist in a suitable solvent, for example, a glycol ether such as 2-methoxyethyl ether (diglyme), ethylene glycol monomethyl ether, propylene glycol monomethyl ether; propylene glycol monomethyl ether acetate; lactates such as ethyl lactate or methyl lactate; propionates, particularly methyl propionate, ethyl propionate and ethyl ethoxy propionate; a Cellosolve ester such as methyl Cellosolve acetate; an aromatic hydrocarbon such toluene or xylene; or a ketone such as methylethyl ketone, cyclohexanone and 2-heptanone. Typically the solids content of the photoresist varies between 5 and 35 wt % based on the total weight of the photoresist composition. Blends of such solvents also are suitable.

Methods and systems of the invention can be used with a variety of imaging wavelengths, for example, radiation having a wavelength of sub-400 nm, sub-300 or sub-200 nm exposure wavelength, with I-line (365 nm), 248 nm and 193 nm being typical exposure wavelengths, as well as EUV and 157 nm. In an exemplary aspect, the photoresists are suitable for use with and imaged at a sub-200 nm wavelength such as 193 nm. At such wavelengths, the use of immersion lithography is typical although dry processing can be used. In immersion lithography, a fluid (i.e., an immersion fluid) having a refractive index of between about 1 and about 2 is maintained between an exposure tool and the photoresist layer during exposure. A topcoat layer is typically disposed over the photoresist layer to prevent direct contact between the immersion fluid and photoresist layer to avoid leaching of components of the photoresist into the immersion fluid.

### Multiple Exposure Lithography

As described above, a further aspect of the invention involves methods of forming an electronic device using a multiple exposure lithographic process. This aspect of the invention will be described with reference to FIGS. 1A-K, which illustrate an, exemplary single etch double exposure process flow in accordance with an exemplary aspect of the invention.

FIG. 1A depicts a substrate 100 which may include various layers and features formed on a surface thereof. The substrate can be of a material such as a semiconductor, such as a silicon or compound semiconductor (e.g., III-V or II-VI), glass, quartz, ceramic, copper and the like. Typically, the substrate is a semiconductor wafer, such as single crystal silicon or compound semiconductor wafer. One or more layers to be patterned 102 are provided over the substrate 100. The layers may include, for example, one or more conductive layers such as layers of aluminum, copper, molybdenum, tantalum, titanium, tungsten, alloys, nitrides or silicides of such metals, doped amorphous silicon or doped polysilicon, one or more dielectric layers such as layers of silicon oxide, silicon nitride, silicon oxynitride, or metal oxides, and combinations thereof. The layers to be etched can be formed by various techniques, for example: chemical vapor deposition (CVD) such as plasma-enhanced CVD or low-pressure CVD; physical vapor deposition (PVD) such as sputtering or evaporation; or electroplating. The particular thickness of the one or more layers to be etched 102 will vary depending on the materials and particular devices being formed.

Depending on the particular layers to be etched and film thicknesses, it may be desired to dispose over the layers 102 a hard mask layer 103 and/or a bottom antireflective coating (BARC) 104 over which a photoresist layer is to be coated. Use of a hard mask layer may be desired, for example, with very thin resist layers, where the layers to be etched require a significant etching depth, and/or where the particular etchant has poor resist selectivity. Where a hard mask layer is used, the resist patterns to be formed can be transferred to the hard mask layer which, in turn, can be used as a mask for etching the underlying layers 102. Suitable hard mask materials and formation methods are known in the art. Typical materials include, for example, tungsten, titanium, titanium nitride, titanium oxide, zirconium oxide, aluminum oxide, aluminum oxynitride, hafnium oxide, amorphous carbon, silicon oxynitride and silicon nitride. The hard mask layer 103 can include a single layer or a plurality of layers of different materials. The hard mask layer can be formed, for example, by chemical or physical vapor deposition techniques.

A bottom antireflective coating 104 may be desirable where the substrate and/or underlying layers would otherwise reflect a significant amount of incident radiation during photoresist exposure such that the quality of the formed pattern would be adversely affected. Such coatings can improve depth-of-focus, exposure latitude, linewidth uniformity and CD control. Antireflective coatings are typically used where the resist is exposed to deep ultraviolet light (300 nm or less), for example, KrF excimer laser light (248 nm), ArF excimer laser light (193 nm), electron beams and soft x-rays. The antireflective coating 104 can comprise a single layer or a plurality of different layers. Suitable antireflective materials and methods of formation are known in the art. Antireflective materials are commercially available, for example, those sold under the AR trademark by The Dow Chemical Company (Midland, Mich. USA), such as AR™40A and AR™124 antireflectants.

A first photosensitive composition such as described above is applied on the substrate over the antireflective layer 104 (if present) to form a first photosensitive layer 106. The first photosensitive composition can be applied to the substrate by spin-coating, dipping, roller-coating or other conventional coating technique. Of these, spin-coating is typical. For spin-coating, the solids content of the coating solution can be adjusted to provide a desired film thickness based upon the specific coating equipment utilized, the viscosity of the solution, the speed of the coating tool and the amount of time allowed for spinning. A typical thickness for the first photosensitive layer 106 is from 600 to 1500 Å. The first photosensitive layer can next be softbaked to minimize the solvent content in the layer, thereby forming a tack-free coating and improving adhesion of the layer to the substrate. The softbake can be conducted on a hotplate or in an oven, with a hotplate being typical. The softbake temperature and time will depend, for example, on the particular material of the photosensitive layer and thickness. Typical softbakes are conducted at a temperature of from 90 to 150° C., and a time of from 30 to 90 seconds.

If the first photosensitive layer 106 is to be exposed with an immersion lithography tool, for example a 193 nm immersion scanner, a topcoat layer (not shown) can be disposed over the photosensitive layer 106. Use of such a topcoat layer can act as a barrier between the immersion fluid and underlying photosensitive layer. In this way, leaching of components of the photosensitive composition into the immersion fluid, possibly resulting in contamination of the optical lens and change in the effective refractive index and transmission properties of the immersion fluid, can be minimized or avoided. Suitable topcoat compositions are known in the art, for example, those described in U.S. Patent Application Pub. No. 2006/0246373A1 and in U.S. patent application Ser. No. 12/655,547, filed Dec. 31, 2009. Such compositions can be applied over the photosensitive layer by any suitable method such as described above with reference to the photosensitive compositions, with spin coating being typical. The topcoat layer thickness is typically λ/4n (or an odd multiple thereof), wherein λ is the wavelength of the exposure radiation and n is the refractive index of the topcoat layer. If a topcoat layer is present, the first photosensitive layer 106 can be softbaked after the topcoat layer composition has been applied rather than prior to topcoat application. In this way, the solvent from both layers can be removed in a single thermal treatment step.

The first photosensitive layer 106 is next exposed to activating radiation 108 through a first photomask 110 to create a difference in solubility between exposed and unexposed regions. For a positive-acting material, as illustrated, the photomask has optically transparent regions corresponding to regions of the photosensitive layer to be removed in a subsequent development step. The exposure energy is typically from 1 to 100 mJ/cm², dependent upon the exposure tool and the components of the photosensitive composition. References herein to exposing a photosensitive composition to radiation that is activating for the composition indicates that the radiation is capable of forming a latent image in the photosensitive composition such as by causing a reaction of the photoactive component, for example, by producing photoacid from a photoacid generator compound. The photosensitive compositions are typically photoactivated by a short exposure wavelength, particularly a sub-400 nm, sub-300 or sub-200 nm exposure wavelength, with I-line (365 nm), 248 nm and 193 nm being typical exposure wavelengths, as well as EUV and 157 nm.

Following exposure of the first photosensitive layer 106, a post-exposure bake (PEB) of the photosensitive layer can be performed at a temperature above the softening point of the layer. The PEB can be conducted, for example, on a hotplate or in an oven. Conditions for the PEB will depend, for example, on the particular material of the photosensitive layer and thickness. The PEB is typically conducted at a temperature of from 80 to 150° C., and a time of from 30 to 90 seconds.

The exposed photosensitive layer 106 is next developed to form a first resist pattern 106′ as shown in FIG. 1B. While the developer material will depend on the particular material of the photosensitive layer 106, suitable developers and development techniques are known in the art. Typical developers include, for example, aqueous base developers such as quaternary ammonium hydroxide solutions, for example, tetra-alkyl ammonium hydroxide solutions such as 0.26 N tetramethylammonium hydroxide.

Following development, the first resist pattern 106′ can optionally be subjected to a dehydration bake to further remove solvent from the resist and cross-link the primary amine component. The dehydration bake can be conducted with a hot plate or oven, and is typically conducted at a temperature of from 100 to 150° C., and a time of from 30 to 90 seconds. A resist-curing composition overcoat layer 112 formed from a composition as described above is next applied over the BARC layer 104 and first resist pattern 106′, as illustrated in FIG. 1C. The resist-curing composition can be applied to the substrate by spin-coating, dipping, roller-coating or other conventional coating technique, with spin-coating being typical. The resist-curing composition layer 112 is applied to a thickness sufficient to completely cover the first resist pattern 106′. A typical thickness for the resist-curing composition layer is from 1 to 2 times the thickness of the underlying resist layer, for example, from 1.01 to 1.3 times the thickness of the underlying resist layer.

With reference to FIG. 1D, following application of the resist-curing composition, the substrate is subjected to a heat-treatment effective to cure at least a surface region 106″ of the first resist pattern 106′. The overcoat heat-treatment can be conducted, for example, on a hotplate or in an oven. While conditions for the heat-treatment will depend, for example, on the particular resist-curing composition and thickness, typical conditions include a temperature of from 110 to 180° C., for example, from 120 to 155° C. or 125 to 140° C., and a heating time of from 30 to 90 seconds.

With reference to FIG. 1E, the excess resist-curing composition 112 is next removed from the substrate surface by rinsing with a material effective to dissolve the material. Suitable removers for the resist-curing composition include, for example, deionized water and/or aqueous base developers such as quaternary ammonium hydroxide solutions, for example, tetra-alkyl ammonium hydroxide solutions such as 0.26 N tetramethylammonium hydroxide. The substrate can next optionally be subjected to a further dehydration bake for removal of residual liquid therefrom. The dehydration bake can be conducted with a hot plate or oven, and is typically conducted at a temperature of from 120 to 180° C., and a time of from 30 to 90 seconds.

A second photosensitive composition as described above is coated over the first resist pattern 106′ and BARC layer 104 to form a second photosensitive layer 114, as shown in FIG. 1F. The second photosensitive composition can be the same or different from the first photosensitive composition and, except as otherwise stated, can be applied and processed in the same manner including the materials and conditions described above with respect to the first photosensitive layer. The second photosensitive layer can next be softbaked. If the second photosensitive layer 114 is to be exposed with an immersion lithography tool, a topcoat layer (not shown) as described above can be disposed over the second photosensitive layer 114. If a topcoat layer is used, the second photosensitive layer 114 can be softbaked after the topcoat layer composition has been applied rather than prior to its application.

With reference to FIG. 1(G), the second photosensitive layer 114 is exposed to activating radiation 108 through a second photomask 116. In the case of a positive-acting material as illustrated, the photomask has optically opaque regions corresponding to portions of the second photosensitive layer to remain after development. For negative-acting materials, the optically opaque regions would correspond with portions of the resist layer to be developed away. The exposed second photosensitive layer 114 is heat-treated in a post-exposure bake and developed, leaving behind resist lines disposed between lines of the first resist pattern 106′ to form a second resist pattern 114′, as depicted in FIG. 1H. Depending on the composition of the second photosensitive layer, it may be desirable that the photosensitive composition have a lower activation energy than the first photosensitive composition. In this way, the exposed second photosensitive layer can be post-exposure baked at a lower temperature than the first photosensitive layer.

Following development of the second photosensitive layer, the BARC layer 104 is selectively etched using the first and second resist patterns 106′, 114′ simultaneously as an etch mask, exposing the underlying hardmask layer 103. The hardmask layer is next selectively etched, again using the first and second resist patterns 106′, 114′ simultaneously as an etch mask, resulting in patterned BARC and hardmask layers 104′, 103′, as shown in FIG. 1I. Suitable etching techniques and chemistries for etching the BARC layer and hardmask layer are known in the art and will depend, for example, on the particular materials of these layers. Dry-etching processes such as reactive ion etching are typical. The first and second resist patterns 106′, 114′ and patterned BARC layer 104′ are next removed from the substrate using known techniques, for example, an oxygen plasma ASH treatment.

Using the hardmask pattern 103′ as an etch mask, the one or more layers 102 are selectively etched, as depicted in FIG. 1J. Suitable etching techniques and chemistries for etching the underlying layers 102 are known in the art, with dry-etching processes such as reactive ion etching being typical. The patterned hardmask layer 103′ can next be removed from the substrate surface using known techniques, for example, a dry-etching process such as reactive ion etching. The resulting structure is a high-density pattern of etched features 102′ as illustrated in FIG. 1K.

In an alternative exemplary method, it may be desirable to pattern the layers 102 directly using the first and second photoresist patterns 106′, 114′ without the use of a hardmask layer. Whether direct patterning with the resist patterns can be employed will depend on factors such as the materials involved, resist selectivity, resist pattern thickness and pattern dimensions.

While the exemplary process described above with respect to FIG. 1 employs a thermal cure for the second photosensitive layer, it should be clear that the resist-curing compositions described herein can alternatively be used for the second layer such that both the first and second photosensitive layers are cured using resist-curing compositions described herein.

Further, while the exemplified process is a single etch double exposure technique, it should be clear that the compositions and methods of the invention are also applicable to higher order patterning processes, for example, single etch triple exposure processes. Use of triple or higher-order patterning in accordance with the invention makes possible the creation of even higher density features than possible with double patterning. In the case of an exemplary triple patterning process, three photolithographic processes are used, each to image a respective photoresist layer. As with the double patterning process, first and second resist patterns are formed, whereby lines of the second resist pattern are disposed between respective adjacent lines of the first resist pattern. A third resist pattern is next formed having lines disposed between adjacent respective lines of the first and second resist patterns. Following formation of the third resist pattern, one or more layers underlying the first, second and third resist patterns can be etched in a single etch process. In the case of a triple patterning process, the first and second resist patterns can be cured using the above-described resist-curing compositions, and the third resist pattern can be thermally cured in a conventional manner, i.e., a resist bake without the use of the resist-curing compositions of the invention. The third resist pattern can alternatively be stabilized using a resist-curing composition in accordance with the invention, as with the first and second resist patterns.

The following non-limiting examples are illustrative of the invention.

### EXAMPLES

### Examples 1-9

### Composition Preparation

Raw material stock solutions were prepared as follows:
1. Polyvinylpyrrolidone (PVP) (average molecular weight=10,000, Sigma-Aldrich) was dissolved in 4-methyl-2-pentanol solvent to make a 25 wt % stock solution (25 wt % PVP/75 wt % solvent);
2. CGPS 352 glycouril crosslinker (Ciba Specialty Chemicals) was dissolved in 4-methyl-2-pentanol solvent to make a 5 weight % stock solution (5 wt % CGPS 352/95 wt % solvent);
3. TML-BPA-MF (5,5′-(1-methylidene)bis[2-hydroxy-1,3-benzenedimethanol] (Honshu Chemical Industry, Japan) was dissolved in 4-methyl-2-pentanol solvent to make a 2 wt % stock solution (2 wt % TML-BPA-MF/95 wt % solvent); and
4. Tris(2-aminoethyl)amine (TAEA) (Sigma-Aldrich) was dissolved in 4-methyl-2-pentanol solvent to make a 1 wt % stock solution (1 wt % TAEA/91 wt % solvent).

The stock solutions were mixed together with additional 4-methyl-2-pentanol solvent in the amounts shown in Table 1. 40 g of each formulation were prepared using 3.3 wt % solids in order to provide a thickness when coated of about 1000 Å at 1500 rotations-per-minute (rpm). These mixtures were rolled on a roller for an hour and then filtered through a Teflon filter with a 0.2 micron pore size.

TABLE 1

| | Stock solution weight in grams (wt % based on total solids) | | | | | |
|---|---|---|---|---|---|---|
| | | CGPS | TML-BPA- | | | 4-methyl- |
| Example | PVP | 352 | MF | | TAEA | 2-pentanol |
| 1 | 4.382 (83.0) | 2.640 (10.0) | 3.300 | (5.0) | 2.640 (2.0) | 27.038 |
| 2 | 3.696 (70.0) | 3.960 (15.0) | 6.600 | (10.0) | 6.600 (5.0) | 19.144 |
| 3 | 4.488 (85.0) | 1.320 (5.0) | 3.300 | (5.0) | 6.600 (5.0) | 24.292 |
| 4 | 4.435 (84.0) | 1.320 (5.0) | 6.600 | (10.0) | 1.320 (1.0) | 26.325 |
| 5 | 4.435 (84.0) | 2.640 (10.0) | 3.300 | (5.0) | 1.320 (1.0) | 28.305 |
| 6 | 4.118 (78.0) | 2.640 (10.0) | 6.600 | (10.0) | 2.640 (2.0) | 24.002 |
| 7 | 3.854 (73.0) | 3.960 (15.0) | 6.600 | (10.0) | 2.640 (2.0) | 22.946 |
| 8 | 4.488 (85.0) | 2.640 (10.0) | 0.000 | (0.0) | 6.600 (5.0) | 26.272 |
| 9 | 4.435 (84.0) | 3.960 (15.0) | 0.000 | (0.0) | 1.320 (1.0) | 30.285 |

### Example 10

### Double Pattern Formation

### Wafer Preparation

300 mm silicon wafers were processed as follows. The wafers were spin-coated with AR™40A antireflectant (The Dow Chemical Company) to form a first bottom antireflective coating (BARC) on a TEL CLEAN TRACK™ LITHIUS™ i+coater/developer. The first BARC-coated wafers were baked for 60 seconds at 215° C. to yield a first BARC film thickness of 75 nm. A second BARC layer was coated over the first BARC using AR™124 antireflectant (The Dow Chemical Company). The wafers were baked at 205° C. for 60 seconds to generate a 23 nm top BARC layer. These wafers were used for subsequent patterning of the first lithography (L1) images as described below.

### First Lithography (L1)

EPIC™ 2096 photoresist (The Dow Chemical Company) was coated on the dual BARC-coated wafers and soft-baked (SB) at 120° C. for 60 seconds on a TEL CLEAN TRACK™ LITHIUS™ i+coater/developer to provide a first resist layer thickness of 950 Å. A topcoat layer was formed over the first resist layer and exposed through a binary reticle having line and space patterns as shown in FIG. 2A using an ASML TWINSCAN™ XT:1900i immersion scanner with a numerical aperture of 1.35 and dipole illumination (0.89 outer sigma/0.76 inner sigma). The critical dimension (CD) on the reticle included 45 nm lines at 90 nm pitch (45 nm 1:1 lines and spaces). The reticle was oriented in such a way that the patterned lines and spaces were in a horizontal direction in each die as illustrated in FIG. 2A. Various CDs were printed on the wafer at a 90 nm pitch with different exposure doses. The die were imaged with a fixed depth of focus and an incremental change of exposure dose such that within each row, the exposure dose increased from left to right with the notch on the wafer in the down position. The wafers were then post-exposure baked (PEB) at 100° C. for 60 seconds and developed for 12 seconds using MEGAPOSIT™ MF-26A developer (The Dow Chemical Company) to render L1 patterns.

### Curing of L1 Resist Image

The L1-patterned wafers were subjected to a dehydration bake process at 120° C. for 60 seconds. The wafers were next spin-coated with a respective resist-curing composition of Examples 1-10 at 1500 rpm to provide a thickness of about 1000 Å on a bare silicon wafer. The wafers were then baked at 130° C. for 60 seconds to cure the L1 patterns on the above-described coater/developer. The wafers were next rinsed with MEGAPOSIT MF-26A developer to remove excess resist-curing composition.

### Second Lithography (L2)

The cured L1-patterned wafers were subjected to a dehydration bake at 150° C. for 60 seconds. The wafers were next coated with EPIC™2098 photoresist (The Dow Chemical Company) and soft-baked at 120° C. for 60 seconds on the above-described coater/developer, resulting in a film thickness of 650 Å (as measured on a bare silicon wafer). A topcoat layer was formed over the second resist layer. The topcoat and second resist layers were exposed and developed to generate second (L2) resist patterns using the same scanner, settings and reticle as in the L1 process, the only difference being that the wafers were rotated by 90 degrees with respect to the L1 orientation, as shown in FIGS. 2B and 2C. The resulting L2 patterns were oriented in the vertical direction in each die with the notch down, thereby forming a cross grid together with the lines and spaces in the L1 patterns which were oriented in the horizontal direction, as shown in FIG. 2D.

### Example 11

### Composition Preparation

23.4 g of PVP stock solution (25 wt % in 4-methyl-2-pentanol), 0.75 g of CGPS 352 (Ciba Specialty Chemicals), 0.75 g of 1,4-benzenedimethanol (Sigma-Aldrich), 15 g of TAEA stock solution (1 wt % in 4-methyl-2-pentanol) and 110.1 g of 4-methyl-2-pentanol were added to a 200 mL glass bottle. This mixture was rolled on a roller for five hours and then filtered through a Teflon filter with a 0.2 micron pore size, to make a 150 g solution with 5 wt % solids.

### Example 12

### Composition Preparation

6.24 g of PVP stock solution (25 wt % in 4-methyl-2-pentanol), 10 g of CGPS 352 stock solution (2 wt % in 4-methyl-2-pentanol), 10 g of TML-BPA-MF stock solution (2 wt % in 4-methyl-2-pentanol), 4 g of the TAEA stock solution (1 wt % in 4-methyl-2-pentanol) and 9.75 g of 4-methyl-2-pentanol were added to a 100 mL glass bottle. The mixture was rolled on a roller for five hours and then filtered through a Teflon filter with a 0.2 micron pore size, to make a 40 g solution with 5 wt % solids.

### Example 13

### Composition Preparation

6.44 g of PVP polymer stock solution (25 wt % in 4-methyl-2-pentanol), 10 g of CGPS 352 stock solution (2 wt % in 4-methyl-2-pentanol), 7.5075 g of TML-BPA-MF stock solution (2 wt % in 4-methyl-2-pentanol), 4 g of TAEA solution (1 wt % in 4-methyl-2-pentanol) and 12.0525 g of 4-methyl-2-pentanol were added to a 100 mL glass bottle. This mixture was rolled on a roller for five hours and then filtered through a Teflon filter with a 0.2 micron pore size, making a 40 g solution with 5 wt % solids.

### Example 14

### Composition Preparation

37.184 g of PVP polymer, 4.48 g of CGPS 352, 2.24 g of TML-BPA-MF and 955 g of 4-methyl-2-pentanol were added to a container. This mixture was rolled on a roller for 7 hours and 0.896 g of TAEA was then added to the container. This mixture was filtered through a Teflon filter with a 0.2 micron pore size, making a 1000 g solution with 4.48 wt % solids.

TABLE 3

| | wt % based on total solids | | | | | wt % solids |
|---|---|---|---|---|---|---|
| | | CGPS | TML-BPA- | | | based |
| Example | PVP | 352 | MF | BDM | TAEA | on comp |
| 11 | 78 | 10 | — | 10 | 2 | 5 |
| 12 | 78 | 10 | 10 | — | 2 | 5 |
| 13 | 80.5 | 10 | 7.5 | — | 2 | 5 |
| 14 | 83 | 10 | 5 | — | 2 | 5 |

### Example 15

### Double Pattern Formation

Double patterning was conducted using the resist-curing composition of Example 11 with the procedures described above in Example 10, with exception of the following. EPIC™ 2096 photoresist (The Dow Chemical Company) was used for both the L1 and L2 photoresist layers. The L1 resist was coated to provide a 1200 Å thickness and the resist-curing composition was coated at a spin speed to yield a 1400 Å thickness on a bare silicon wafer. The wafers were rinsed with MEGAPOSIT MF-26A developer or deionized water to remove excess resist-curing composition. The L2 resist was coated at a spin speed to yield 1000 Å on a bare silicon wafer.

### Example 16

### Double Pattern Formation

Double patterning was conducted using the resist-curing compositions of Examples 11-14 with the procedures described above in Example 15, with exception that EPIC 2098 (The Dow Chemical Company) photoresist was used as the L2 resist.

While the invention has been described in detail with reference to specific embodiments thereof, it will be apparent to one skilled in the art that various changes and modifications can be made, and equivalents employed, without departing from the scope of the claims.

What is claimed is:

1. A composition suitable for use in a multiple exposure lithographic process, comprising:
a matrix polymer;
a crosslinker;
a tri- or higher order-functional primary amine; and
a solvent.

2. The composition of claim 1, further comprising a multifunctional aromatic methanol derivative.

3. The composition of claim 1, wherein the matrix polymer is alcohol-soluble and aqueous base-soluble.

4. The composition of any of claims 1, wherein the crosslinker is a compound represented by a formula chosen from the following formulae (G-I), (G-II) and (G-III): 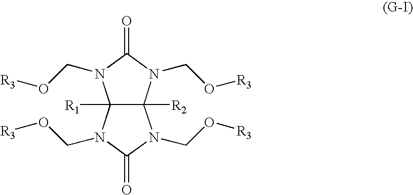
wherein R₁ and R₂ are independently chosen from hydrogen and optionally substituted alkyl, and R₃ is chosen from optionally substituted alkyl; 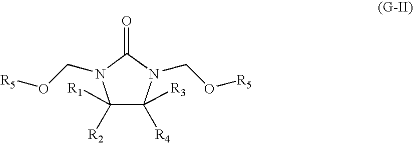
wherein: R₁, R₂, R₃ and R₄ are independently chosen from hydrogen, optionally substituted alkyl such as C1 to C6 alkyl, alkenyl, alkoxy and aryl, and R₅ is chosen from optionally substituted alkyl; and 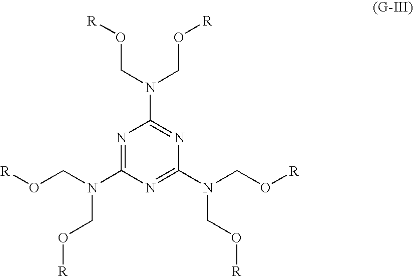
wherein R is chosen from optionally substituted alkyl.

5. The composition of claim 1, wherein the primary amine is a polyamine or a poly(allyl amine).

6. The composition of claim 1, wherein the solvent comprises an alcohol and/or an alkyl ether.

7. A method of forming an electronic device using a multiple exposure lithographic process, comprising:
(a) providing a semiconductor substrate comprising one or more layers to be patterned;
(b) applying a layer of a first photosensitive composition over the one or more layers to be patterned;
(c) exposing the layer of the first photosensitive composition to activating radiation through a first photomask;
(d) heat-treating the exposed layer of the first photosensitive composition in a first post-exposure bake;
(e) developing the exposed, heat-treated layer of the first photosensitive composition to form a first resist pattern;
(f) applying a layer of a resist-curing composition over the one or more layers to be patterned and the first resist pattern, the resist-curing composition comprising a matrix polymer, a crosslinker, a multifunctional aromatic methanol derivative, a tri- or higher order-functional primary amine and a solvent;
(g) heat-treating the resist-curing composition-coated substrate, thereby curing at least a portion of the first resist pattern;
(h) removing excess resist-curing composition from the substrate;
(i) applying a layer of a second photosensitive composition over the one or more layers to be patterned and the first resist pattern;
(j) exposing the layer of the second photosensitive composition to activating radiation through a second photomask;
(k) heat-treating the exposed layer of the second photosensitive composition in a second post-exposure bake;
(l) developing the exposed, heat-treated layer of the second photosensitive composition to form a second resist pattern; and
(m) etching the one or more layers to be patterned using the first and second resist patterns simultaneously as an etching mask.

8. The method of claim 7, wherein the excess resist-curing composition is removed from the semiconductor substrate in an aqueous base rinse.

9. The method of claim 7, further comprising baking the substrate between steps (h) and (i).

10. The method of claim 7 wherein the first post-exposure bake is conducted at a higher temperature than the second post-exposure bake.
